(19) United States
(12) Patent Application Publication
(10) Pub. No.: US 2004/0183408 A1
(43) Pub. Date: Sep. 23, 2004

(54) Actuator

(75) Inventors: Miguel Levy, Chassell, MI (US); Shankar R. Ghimire, Houghton, MI (US); Kee S. Moon, Houghton, MI (US)

Correspondence Address: Joseph A. Gemignani, Michael Best & Friedrich LLP, 100 East Wisconsin Avenue, Milwaukee, WI, 53202-4108, US

(73) Assignee: Board of Control of Michigan Technological University, Houghton, MI

(21) Appl. No.: 10/394,987

(22) Filed: Mar. 21, 2003

(51) Int. Cl. H01L 41/047

(52) U.S. Cl. 310/365

(57) ABSTRACT

An actuator including a piezoelectric film. The film has a first side, a second side, and a thickness between the first side and the second side. The actuator also includes a first electrode adjacent to the first side of the film, and a second electrode adjacent to the second side of the film. The first electrode and the second electrode are configured to establish an electric field gradient across the thickness of the film when the first electrode and the second electrode are energized. The gradient causes deflection of the film. The gradient includes a difference between a field component substantially near the first side of the film and a field component substantially near the second side of the film.

### BACKGROUND OF THE INVENTION

The present invention generally relates to actuators and in one arrangement, more particularly, to monomorphic piezoelectric actuators.

### SUMMARY OF THE INVENTION

In one embodiment, the invention provides an actuator including a piezoelectric film. The film has a first side, a second side, and a thickness between the first side and the second side. The actuator also includes a first electrode adjacent to the first side of the film, and a second electrode adjacent to the second side of the film. The first electrode and the second electrode are configured to establish an electric field gradient across the thickness of the film when the first electrode and the second electrode are energized. The gradient causes deflection of the film. The gradient includes a difference between a field component substantially near the first side of the film and a field component substantially near the second side of the film.

In another embodiment, the present invention provides an actuator including a piezoelectric film and a plurality of electrodes. The film has a first side, a second side, and a thickness between the first side and second side. The plurality of electrodes is positioned adjacent to the piezoelectric film. The plurality of electrodes establishes an electric field gradient across the thickness of the film when the plurality of electrodes is energized. The gradient deflects the film.

In a further embodiment, the invention provides a method of converting an electrical input to a mechanical output by way of a single piezoelectric film. The film has a first side, a second side, and a thickness. The method includes positioning a first electrode adjacent one of the first side and the second side of the piezoelectric film and positioning a second electrode adjacent one of the first side and the second side of the piezoelectric film. The method also includes energizing the first electrode and the second electrode to produce an electric field gradient across the thickness of the piezoelectric film, and deflecting the film in response to the presence of the electric field gradient.

Other features and advantages of the invention will become apparent by consideration of the detailed description and accompanying drawings.

### BRIEF DESCRIPTION OF THE DRAWINGS

In the drawings:

FIG. 1 is a schematic view of an actuator.

FIG. 2 is a schematic view of another construction of an actuator.

FIG. 3 is a schematic view of yet another construction of an actuator.

FIG. 4 is a schematic view of a still another construction of an actuator.

FIG. 5 is a schematic view of a further construction of an actuator.

FIG. 6 is a partial schematic view of an actuator, such as the actuator shown in FIG. 5, and an accompanying electric field.

FIG. 7 is a graph illustrating vertical field components of an electric field near the topside of an actuator, such as the actuator shown in FIG. 6, and near the bottom side of the actuator.

FIG. 8 is a graph illustrating an average horizontal field component and an average vertical field component across a thickness of an actuator, such as the actuator shown in FIG. 6.

FIG. 9 is a graph illustrating vertical components of an electric field across an actuator, such as the actuator shown in FIG. 2.

FIG. 10 is a graph illustrating horizontal components of an electric field across an actuator, such as the actuator shown in FIG. 2.

FIG. 11 is a graph illustrating the averages of the components illustrated in FIGS. 9 and 10 across the thickness of an actuator, such as the actuator shown in FIG. 2.

FIG. 12 is a schematic view of an actuator, such as the actuator shown in FIG. 1, illustrating one construction of a mechanical output.

FIG. 13 is a graph illustrating a vertical displacement of an actuator, such as the actuator shown in FIG. 2.

FIG. 14 is a graph illustrating vertical displacements of various actuators.

FIG. 15 is a graph illustrating a hysteresis profile of an actuator.

FIG. 16 is another schematic view of a construction of an actuator, such as the actuator shown in FIG. 3.

FIG. 17 is a graph illustrating the vertical displacement of an actuator, such as the actuator shown in FIG. 16.

FIG. 18 is a another graph illustrating the vertical displacement of an actuator, such as the actuator shown in FIG. 16.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. The terms “mounted,” “connected,” and “coupled” are used broadly and encompass both direct and indirect mounting, connecting, and coupling. Further, “connected” and “coupled” are not restricted to physical or mechanical connections or couplings.

### DETAILED DESCRIPTION

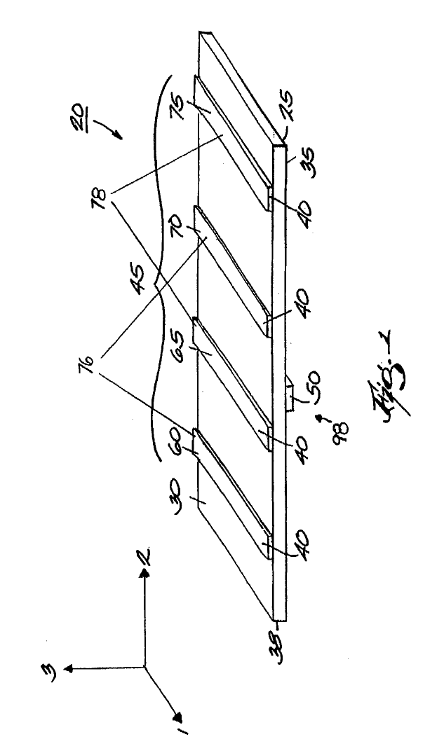

FIGS. 1-5 illustrate first, second, third, fourth and fifth monomorphic actuators 20, 21, 22, 23, and 24. Unless specified otherwise, the constructions below are in reference to actuator 20. However, unless specified otherwise (either explicitly or implicitly), the construction for actuator 20 applies to actuators 21, 22, 23 and 24. As used herein, the term “monomorph actuator” and “monomorphic actuator” is broadly construed to mean an actuator having a single film, such as piezoelectric film 25, in addition to the electrodes (discussed below). In some constructions, the actuator 20 includes a single piezoelectric film 25 having a topside 30, a bottom side 35, and a thickness 38 between the topside 30 and bottom side 35. In other constructions, the actuator 20 is not monomorphic and includes two or more piezoelectric films 25.

In some constructions, the piezoelectric film 25 includes (1-x)Pb(Zn_{1/3}Nb_{2/3})O₃-xPbTiO₃ (“PZN-PT”) or (1-x)Pb(Mg_{1/3}Nb_{2/3})O₃-xPbTiO₃ (“PMN-PT”). In one construction, the actuator 20 includes <001>-orientated PZN-PT crystals having a piezoelectric modulus coefficient d₃₃ of approximately 1,000 pC/N to approximately 2,500 pC/N, a piezoelectric coupling coefficient approximately larger than 0.9, and strain levels of approximately 1.2%. In other constructions, the piezoelectric film 25 includes Pb(ZrTi)O₃ (“PZT”), LiNbO₃ (“lithium niobate”), another single-crystal lead oxide material or another suitable piezoelectric material. In further constructions, the film 25 could include dopants or impurities.

In the constructions shown in FIGS. 1-5, the film 25 has a length of approximately 200-μm, a width of approximately 50-μm, and a height or thickness 38 of approximately 10-μm. In other constructions, the film 25 can vary in height, length, and width. In some constructions, the film 25 shown in FIGS. 1-5 is poled along the 3-axis. In other constructions, the film 25 is poled by using electrodes (discussed below), as the pole pieces. The temperature is raised above the Curie temperature in an electric field and slowly cooled back down to room temperature.

In some constructions and in some aspects, the actuator 20 includes one or more electrodes positioned adjacent one of the topside 30 and the bottom side 35 of the film 25. In the constructions illustrated in FIGS. 1-4, the actuators 20, 21, 22, and 23 include a plurality of first electrodes 40 positioned on the topside 30 of the film 25. However, in other constructions, the plurality of first electrodes 40 can be positioned on the bottom side 35 of the film 25, positioned within the film 25, or integral with the film 25.

The plurality of first electrodes 40 can be constructed of chromium (“Cr”) or of other metallic materials. In some constructions, the plurality of first electrodes 40 are formed from an evaporative Cr layer deposited on the film 25. In some constructions, the Cr layer is approximately 50-nm thick and can be deposited onto the film 25 by photolithography, shadow masking, metal evaporation and/or other suitable deposition techniques. In other constructions, the topside 30 or the bottom side 25 of the film is coated with a Cr layer and then transferred to an electrode pad (e.g., electrodes positioned on a substrate or pad) with the Cr layer down.

As shown in FIGS. 1-4, each electrode in the plurality of first electrodes 40 has substantially the same length and width. In these constructions, each first electrode 40 is approximately 50-μm long and approximately 20-μm wide. In some constructions, the width and length of each first electrode 40 are different from the width and length of the first electrodes 40 as shown in FIGS. 1-4.

In some constructions, the plurality of first electrodes 40 creates an electrode pattern, such as, for example, a first electrode pattern 45 created by the plurality of first electrodes 40. The electrode pattern can be defined by, but is not limited to, the position of the electrode or electrodes on the actuator 20, the position of the electrode with respect to another electrode, the orientation of the electrode(s), the spacing between two or more electrodes, the size and/or shape of the electrode(s), the composition of the electrode(s), the number of electrodes, and/or any variations between electrodes (e.g., size, shape, spacing, orientation, composition, position relative to a reference point, etc.). The first electrode pattern 45 illustrated in FIGS. 1-4 is defined by positioning each electrode within the plurality of first electrodes 40 parallel to one another and equally spaced.

In some constructions and in some aspects, the actuator 20 further includes a second electrode or a plurality of second electrodes positioned on the other one of the topside 30 and bottom side 35 of the film 25. As shown in FIG. 1, the actuator 20 includes a second electrode 50 located substantially near the middle or center 98 of the bottom side 35 of the film 25. In the construction shown, the second electrode 50 is a conductive epoxy cover ranging from approximately 50-μm to approximately 100-μm in diameter. In other constructions, the second electrode 50 is formed from an evaporative Cr layer deposited on the film 25. In some constructions, the Cr layer is approximately 50-nm thick and can be deposited onto the film 25 by photolithography, shadow masking, metal evaporation and/or other suitable deposition techniques.

The second electrode 50 is illustrated in FIG. 1 as being thicker than the first electrodes 40 positioned on the topside 30 of the film 25. However, this is for illustrative purposes. In other constructions, the second electrode 50 has a thickness that is less than or the same as the thickness of the first electrodes 40.

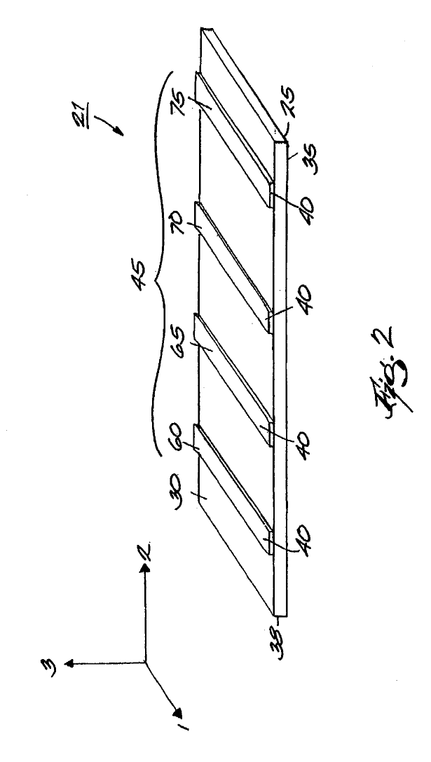

In some constructions and in some aspects, such as the construction illustrated in FIG. 2, the actuator 21 does not include a second electrode 50. As shown in FIG. 2, the actuator 21 includes the first plurality of electrodes 40 positioned on the topside 30 of the piezoelectric film 25 and does not include any electrodes positioned on the bottom side 35. In other constructions, the first plurality of electrodes 40 are positioned on the bottom side 35 of the film 25, and the topside 30 of the film 25 is without any electrodes.

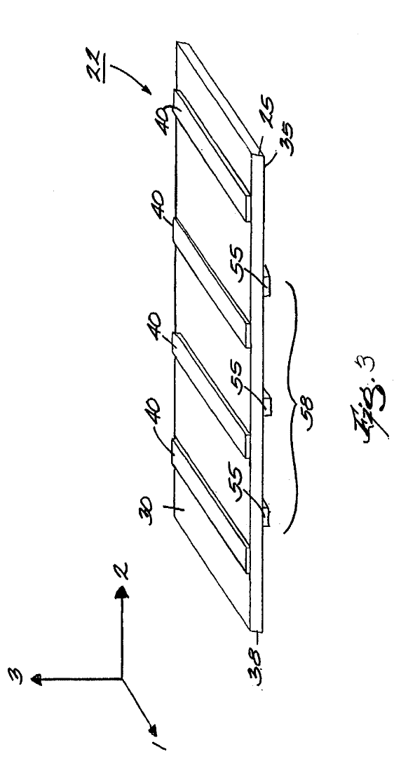

In some constructions and in some aspects, such as the construction illustrated in FIG. 3, the actuator 22 includes a plurality of second electrodes 55 located on the bottom side 35 of the film 35 instead of a single second electrode 50 (shown in FIG. 1). In the construction shown, each electrode in the plurality of second electrodes 55 is similar to the second electrode 50, as shown in FIG. 1, and can be formed in a similar manner as the second electrode 50. In some constructions, such as, for example, the construction shown in FIG. 3, the plurality of second electrodes 55 includes fewer electrodes than the plurality of first electrodes 40. In other constructions, the plurality of second electrodes 55 includes more electrodes than the first plurality 40 or the same number of electrodes as the first plurality 40.

In some constructions, the second electrodes 55 can also vary in thickness, shape, size, composition, spacing, arrangement and/or other characteristics from the electrodes of the first plurality 40. Furthermore, the plurality of second electrodes 55 can have a second electrode pattern that is substantially similar to the first electrode pattern 45 or that differs from the first electrode pattern 45, such as, for example, electrode pattern 58 shown in FIG. 3.

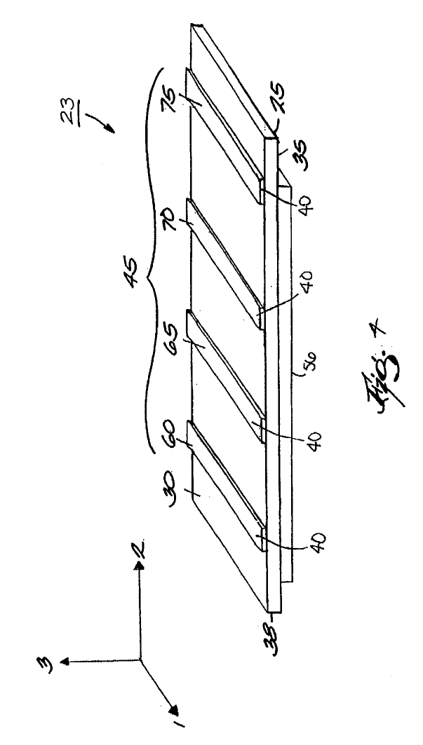

In some constructions and in some aspects, such as the construction illustrated in FIG. 4, the actuator 23 includes a large or continuous electrode 56 located on the bottom side 35 of the film 25 instead of the single second electrode 50 (shown in FIG. 1) or the plurality of second electrodes 55 (shown in FIG. 3). In the illustrated construction, the continuous electrode 56 extends the entire width of the film 25, but does not extend the entire length of the film 25. In other constructions, the continuous electrode 56 extends the entire length of the film 25. In further constructions, the continuous electrode 56 does not extend the entire width of the film 25. The continuous electrode 56 is formed in a similar manner as the second electrode 50.

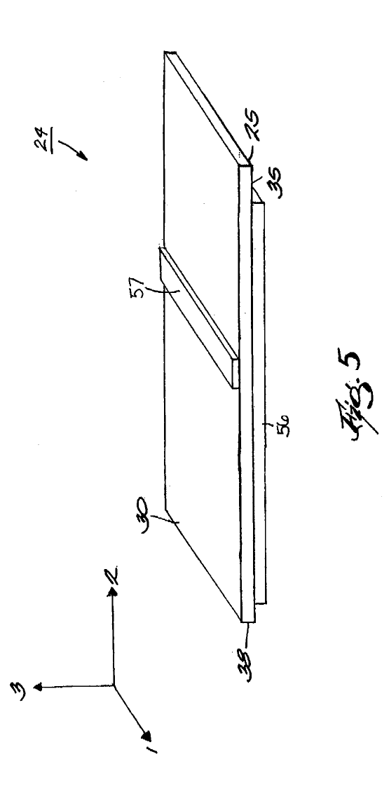

In some constructions and in some aspects, such as the construction illustrated in FIG. 5, the actuator 24 includes a single first electrode 57 positioned on the topside 30 of the film 25 and the continuous electrode 56 positioned on the bottom side 35 of the film 25. As shown in FIG. 5, the single first electrode 57 is smaller in size and shape than the continuous electrode 56. In other constructions, the single first electrode 57 is positioned on the bottom side 35 of the film 25, and the continuous electrode 56 is positioned on the topside 30 of the film 25. In other constructions, the first electrode 57 and the continuous electrode 56 vary in shape, size and/or position.

In some constructions and in some aspects, the actuator 20, in operation, can produce either a mechanical output or an electrical output depending on the type of input used to activate the actuator 20. In some constructions, if a mechanical input is used (e.g., a stress and/or strain applied to the film 25, etc.), the actuator 20, due to the piezoelectric properties of the film 25, produces an electrical output (e.g., a voltage across the topside 30 and the bottom side 35, etc.) having a relationship (e.g., a proportional relationship) to the amount of stress and/or strain applied to the film 25. That is, the actuator 20 can act as a sensor, and, unless limited otherwise, the term “actuator” should be interpreted broadly to cover a sensor.

In some constructions, if an electrical input is used (e.g., a voltage and/or current applied to the film 25, an electric field within and/or near the film 25, etc.), the actuator 20 produces a mechanical output (e.g., a flexing action within the film 25, a displacement of the actuator 20 relative to a base or starting position, etc.) having a relationship (e.g., a proportional relationship) to the amount of voltage and/or current applied to the film 25. In some constructions and in some aspects of the invention, the actuator 20 is capable of producing a mechanical output in response to an electrical input with a single film, such as, for example, the piezoelectric film 25.

In some constructions and in some aspects, the plurality of first electrodes 40 and the second electrode 50 (or the plurality of second electrodes 55, the continuous electrode 56 or the single first electrode 57) are energized to create an electric field within the film 25 to produce a mechanical output (e.g., flexing action, etc). The electrodes 40, 50, 55, 56, and/or 57 are energized by one or more driving circuits. In some constructions, the plurality of first electrodes 40 are digitized, that is, the electrodes 40 are energized with high and/or low voltage signals, the high voltage signal being greater than the low voltage signal. For example, a high voltage signal of approximately 150 V and/or a low voltage signal of approximately 0 V are used. In some constructions, the magnitudes of the high and/or low voltage signals are greater than or less than 150 V and/or 0 V, respectively.

In other constructions, one or more oscillatory signals are used to excite the electrodes 40, 50, 55, 56, and/or 57. For example, in some constructions, a first oscillatory signal having a first magnitude and a first phase is used to excite electrodes positioned on one side, such as the topside 30, of the film 25. In other constructions, the first oscillatory signal is used to excited one or more electrodes positioned on the topside 30 of the film 25, and a second oscillatory signal having a second magnitude and a second phase is used to excite one or more additional electrodes positioned either on the topside 30 or the bottom side 35 of the film 25. In these constructions, the first magnitude may not equal the second magnitude and/or the first phase may not equal the second phase. In some constructions, the first oscillatory signal has a high voltage magnitude, and the second oscillatory signal has a low voltage magnitude.

In further constructions, the first electrodes 40 are digitized such that alternating first electrodes 40 are energized with high and low voltages, respectively, while grounding the second electrode 50, one or more electrodes in the second plurality 55 or the continuous electrode 56. In other constructions, other electrodes are digitized, such as, for example, the second plurality of electrodes 55 or a combination of electrodes 40, 50, 55, 56, and/or 57.

As shown in FIG. 1, for example, the plurality of first electrodes 40 includes a first electrode 60, a second electrode 65, a third electrode 70, and a fourth electrode 75. In some constructions, the plurality of electrodes 40 are arranged into groups, such as, for example, a first group 76 and a second group 78. The first group 76 includes the first electrode 60 and the third electrode 70, and the second group 78 includes the second electrode 65 and the fourth electrode 75. In this construction, the plurality of first electrodes 40 are digitized by energizing the first group 76 (i.e., the first electrode 60 and the third electrode 70) with a high voltage and energizing the second group 78 (i.e., the second electrode 65 and fourth electrode 75) with a low voltage.

In some constructions, the high voltage can fall within a range of approximately 50 V to approximately 200 V, and the low voltage can fall within a range of approximately 0 V to approximately 50 V. In some constructions, the low voltage can fall within a range of approximately −200 V to approximately 0 V. In other constructions, the high voltage is a voltage greater than the low voltage. In some constructions, such as, for example, the construction shown in FIG. 1, the second electrode 50 is grounded. In other constructions, the plurality of second electrodes 55 can either be digitized, grounded, or energized with substantially the same potential or signal.

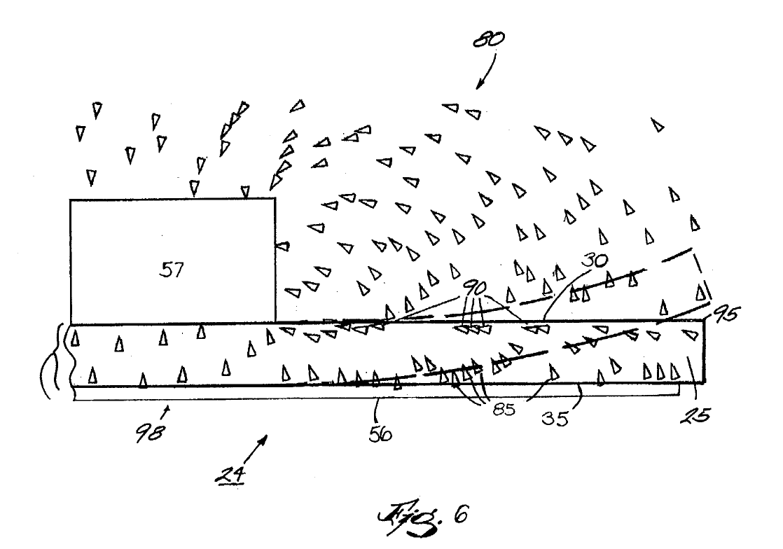

In some constructions and in some aspects, such as, for example, the construction shown in FIG. 6, the single first electrode 57 and the continuous electrode 56 are arranged and energized so as to create an electric field gradient (e.g., electrical input) near and/or within the film 25 to produce flexing of the actuator (e.g., mechanical output). In other words, the single first electrode 57 and the continuous electrode 56 produce a difference in magnitude and/or direction between the field components 85 of an electric field 80 located near the bottom side 35 of the film 25 and the field components 90 of the electric field 80 located near the topside 30 of the film 25. In the illustrated construction, the actuator 24 produces an electric field gradient using the single first electrode 57 and the continuous electrode 56. However, the concept of the electric field gradient shown in FIG. 6 is generalizable to the other configurations illustrated in FIGS. 1-4.

In some constructions and in some aspects, the difference between the field components 85 and 90 of the electric field 80 generates axial strains in the film 25 due to the transverse piezoelectric coupling of the film 25. That is, the field distribution 80 leads to a differential contraction of the topside 30 relative to the bottom side 35 and contributes to the flexing action and/or displacement of the film 25 (shown in phantom). In some constructions, the topside 30 of the film 25 contracts more than the bottom side 35 of the film 25. In other constructions, the bottom side 35 contracts more than the topside 30.

In the construction illustrated in FIG. 6, first electrode 57 is energized with a high voltage signal of approximately 90 V, and the continuous electrode 56 is energized with a low voltage signal of approximately 0 V. Also shown in the illustrated construction (i.e., in FIGS. 5 and 6), the first electrode 57 is deposited substantially near the middle 98 of the film 25 and on the topside 30 of the film 25. In the illustrated construction, the film 25 is poled along the 3-axis. In other constructions, the film 25 is poled by using the electrodes, such as, for example, the single first electrode 57 and the continuous electrode 56, as the pole pieces. The temperature is raised above the Curie temperature in an electric field and slowly cooled back down to room temperature.

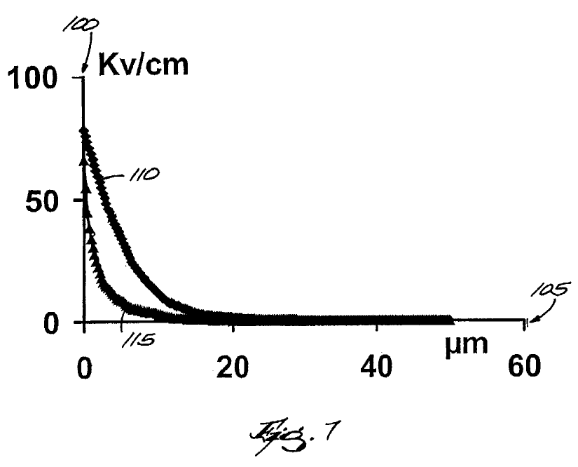

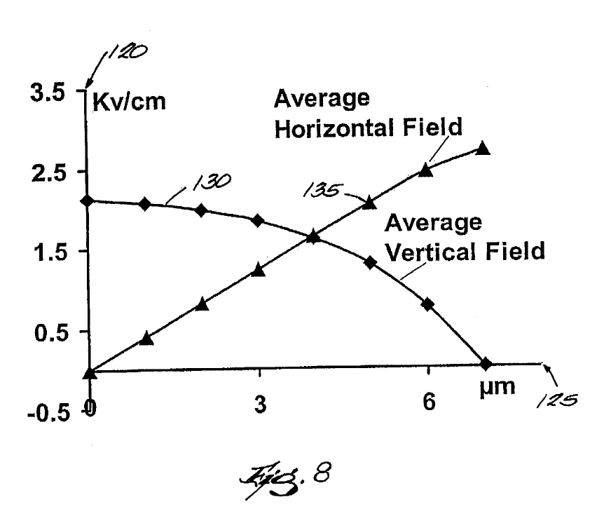

Still referring to FIG. 6, the field distribution 80 across the thickness 38 of the film 25 includes vertical field components and horizontal field components of varying overall strength between the edge 95 of the film 25 and the center 98 of the film 25. Numerical calculations based on three-dimensional finite element analysis show the field lines 80 to be predominantly vertical near the topside 30 of the film 25 with a large horizontal component near the bottom side 35 of the film 25. Underneath the first electrode 57, the field lines 80 remain vertical throughout the thickness 38 of the film 25. In some constructions, the large permittivity of a PZN-PT film 25 (e.g., approximately 5,000) induces a significant horizontal component of the electric field 80 outside the center or central region 98 of the film 25. This field distribution 80 is also illustrated in FIGS. 7 and 8.

FIG. 7 is a graph illustrating the calculated vertical field components of the electric field near the topside of an actuator, such as, for example, the actuator 24 shown in FIG. 6, and the vertical field components near the bottom side of the actuator 24. Axis 100 represents the strength of the vertical electric field components in kilovolts per centimeter, and axis 105 represents the distance from the first electrode 57 across the length of the actuator 24 in micrometers. Line 110 represents the vertical field components near the bottom side 35, and line 115 represents the vertical field components near the topside 30. In this construction, the actuator 24 is approximately 450-μm long, and the high voltage signal that is applied to the first electrode 57 is approximately 90 V.

As shown in FIG. 7, a substantial difference between the magnitude of the vertical field components located near the topside 30 and those located near the bottom side 35 is present in the actuator 24. The difference between the vertical field components near the topside 30 and the field components near the bottom side 35 (e.g., the difference between line 115 and line 110) contribute to the flexing action exhibited by the actuator 24, as will be discussed below.

FIG. 8 is a graph illustrating the calculated average horizontal field component and the average vertical field component across the thickness of an actuator, such as, for example, the actuator 24 shown in FIG. 6. Axis 120 represents the strength of the average electric field component in kilovolts per centimeter, and axis 125 represents the vertical position across the thickness 38 of the actuator 24 in reference to the bottom side 35 of the actuator 24 in micrometers. Line 130 represents the magnitude of the average vertical field component exterior to the central region 98 and across the thickness 38 of the actuator 24, and line 135 represent the magnitude of the average horizontal field component exterior to the central region 98 and across the thickness 38 of the actuator 24. In this construction, the actuator 24 is approximately 450-μm. The first electrode 57 is energized with a high voltage signal of approximately 90 V.

As shown in FIG. 8, there is a substantial difference present in the actuator 24 between the magnitude of the average vertical field component located throughout the thickness 38 of the actuator 24 and the magnitude of the average horizontal field component located throughout the thickness 38. The difference between the average vertical field component and the average horizontal field component (e.g., the difference between line 130 and line 135) also contribute to the flexing action exhibited by the actuator 24.

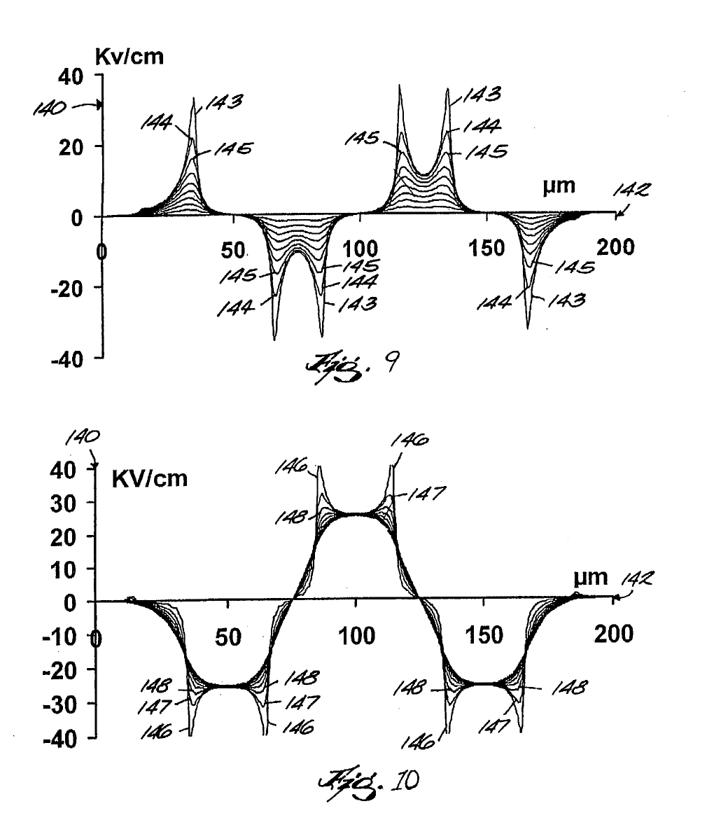

FIG. 9 is a graph plotting the vertical components of the electric field across an actuator, such as, for example, the actuator 21 of FIG. 2. FIG. 10 is a graph plotting the horizontal components of the electric field across an actuator, such as, for example, the actuator 21 of FIG. 2. The graphs illustrated in FIGS. 9 and 10 were constructed by the Maxwell® 3D software program available through Ansoft Corporation. The graphs were based on an actuator, such as the actuator 21 of FIG. 2, having a length of approximately 200-μm, a width of approximately 50-μm, and a height or thickness of approximately 10-μm. The film 25 of the actuator 21 has a dielectric constant ∈ of approximately 5,000. The plurality of digitized first electrodes 40 are energized with alternating signals of approximately 0 V and approximately 100 V. Referring to FIGS. 9 and 10, axis 140 represents the magnitude of the electric field components in kilovolts per centimeter, and axis 142 represents the position along the length of the actuator 21 from one end to the other in micrometers.

As shown in FIG. 9, line 143 represents the strength of the vertical electric field components as measured across the length of the actuator 21 and as measured from the topside 30 (e.g., the side having the plurality of first electrodes 40). Lines 144 and 145 represent the strength of the vertical electric field components as measured across the length of the actuator 21 and as measured from intervals of 1-μm away from the topside 30 of the film 25 toward the bottom side 35. As the distance away from the topside 30 increases and thus, the distance away from the plurality of first electrodes 40 increases, the field strength of the vertical components decreases. This is illustrated by lines 143, 144, and 145.

As shown in FIG. 10, line 146 represents the strength of the horizontal electric field components as measured across the length of the actuator 21 and as measured from the topside 30 (e.g., the side having the first plurality of electrodes 40). Lines 147 and 148 represent the strength of the horizontal electric field components as measured across the length of the actuator 20 and as measured from intervals of 1-μm away from the topside 30 of the film 25 toward the bottom side 35. The strength of the horizontal electric field components slightly decreases as the distance away from the topside 30 increases, as indicated by lines 146, 147, and 148. Comparing the graph of FIG. 10 to the graph of FIG. 9, the strength of the horizontal components does not change as rapidly as the vertical components do.

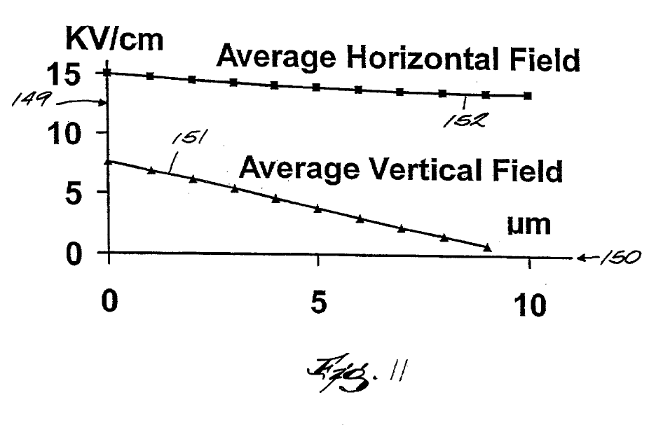

FIG. 11 is a graph illustrating the average vertical component of FIG. 9 and average horizontal component of FIG. 10 at different depths or distances away from the topside 30 of the actuator 21. Axis 149 represents the strength of the average field components in kilovolts per centimeter, and axis 150 represents a distance away from the topside 30 of the actuator 21 in micrometers. Line 151 represents the average vertical component of the electric field as measured from increasing distances away from the plurality of first electrodes 40. Line 152 represents the average horizontal component of the electric field as measured from increasing distances away from the plurality of first electrodes 40.

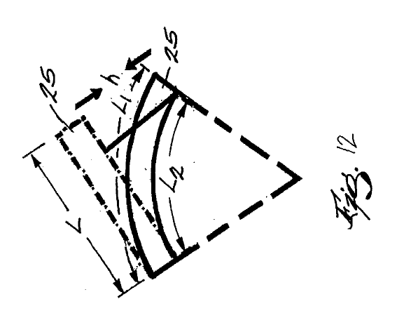

FIG. 12 schematically illustrates one construction of a mechanical output of an actuator, such as, for example, the actuator 20 of FIG. 1. The presence of an electric field gradient, such as, for example, the electric field gradient 80 illustrated in FIGS. 6, 7, and/or 8, causes the actuator 20 to deform or bend relative to the magnitude and/or direction of the field gradient 80 that is applied. In this construction, h is the vertical deflection of an end 95 of the film 25 when an electric field 80 is applied. The vertical deflection h can be expressed by equation e1

$$h = \frac{{L}_{2} 2 t}{Δ L} {sin}^{2 } ( \frac{Δ L}{2 t} ) \qquad [ e1 ]$$

where L is the length of the film 25 in the absence of an electric field, L₂ is the length of the film 25 on the plurality of first electrodes side or topside 30 (e.g., high field side) after deformation, L₁ is the length of the film 25 on the second electrode side or bottom side 35 (e.g., low field side) after deformation, t is the thickness 38 of the film 25, and ΔL is the difference in deformation (e.g., expansion and/or contraction, etc.) at the topside 30 and the bottom side 35.

In some constructions, ΔL is calculated using the equation e2

ΔL=d₃₁Δ\overline{E}*L [e2]

where ΔE is the vertical electric field gradient. In one construction, the vertical electric field gradient ΔE is approximately 7 kV/cm. Using equation e1 and 7 kV/cm as the value of the vertical field gradient ΔE, the vertical deflection h of the end 95 is approximately 1.4-μm.

In some constructions, increasing the length L of the actuator 20 and/or increasing the field difference ΔE can optimize the end deflection h. In some constructions, almost the same size field difference ΔE can be obtained by increasing the number of electrodes included in the first plurality of electrodes 40 spaced in approximately the same manner. Increasing the number of equally spaced first electrodes 40 would produce an end deflection h of about 5.6-μm.

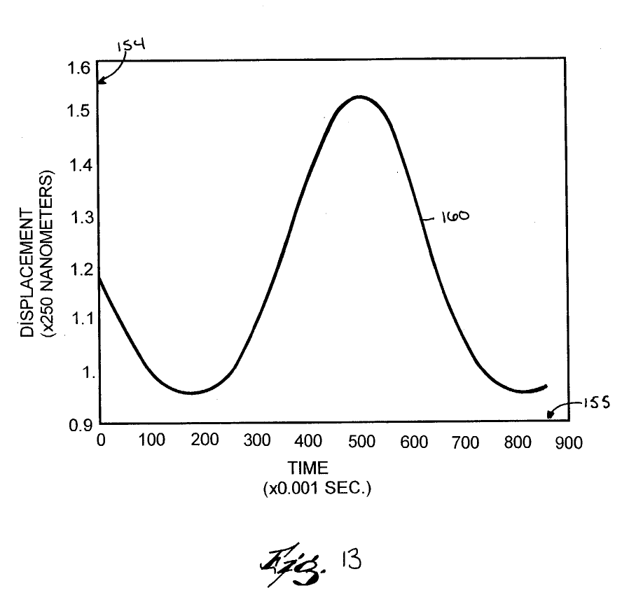

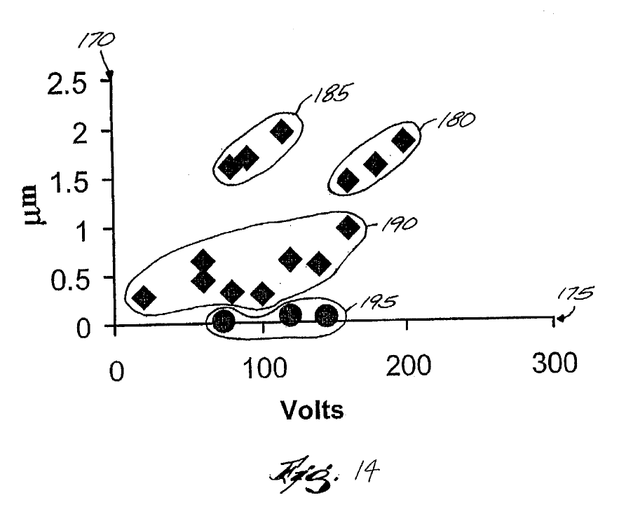

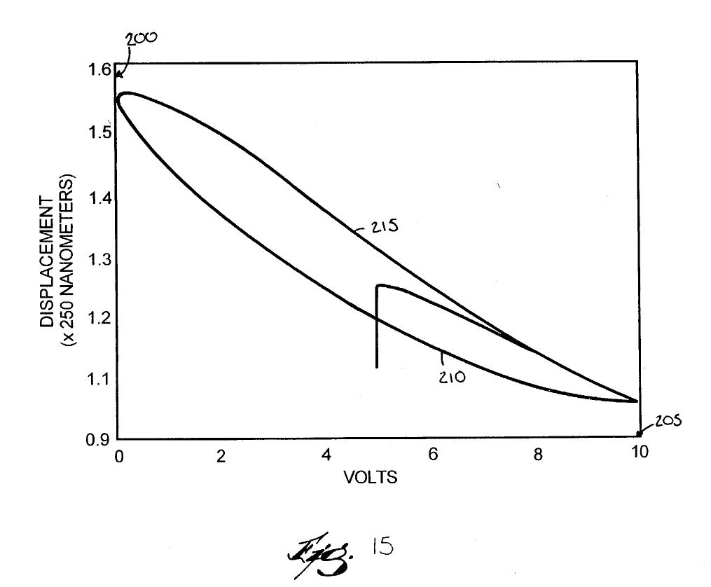

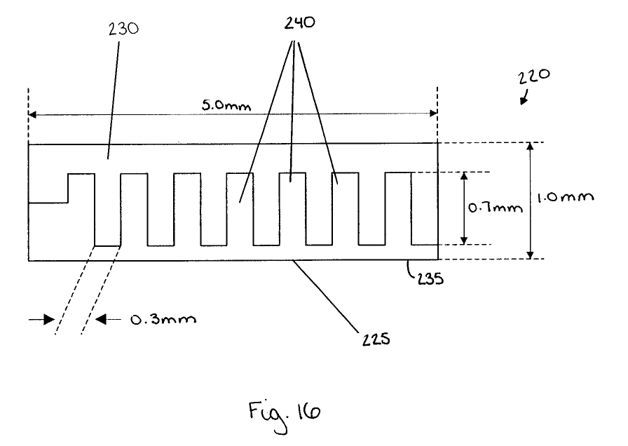

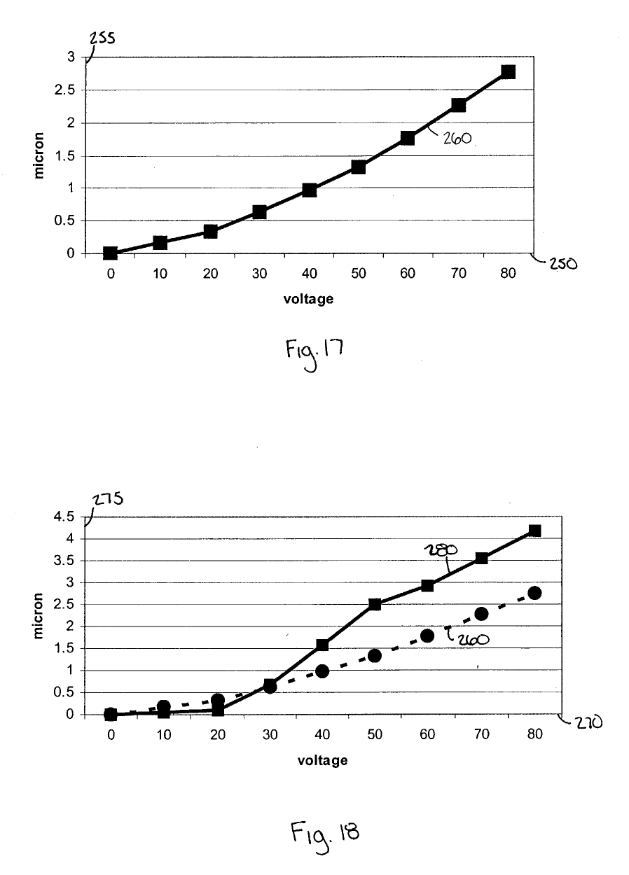

In some constructions, the actuator 20 can be clamped at one of the far ends 95 and can exhibit flexing action or vertical displacement (e.g., mechanical output) near the center 98 of the film 25 and the opposite end 95 when an electric field gradient is applied to the film 25. FIG. 13 shows a plot of the vertical displacement y of the actuator 20 as a function of time. Axis 154 represents the vertical displacement y of the actuator in nanometers (times 250), and axis 155 represents time in seconds (times 0.001). Line 160 represents the displacement profile in an actuator displaying cantilever-bending motion. The actuator 20 is approximately 450 μm long and the varying voltage signal used to energize the plurality of first electrodes 40 ranges from approximately 0V to approximately 10 V.

In some constructions and in some aspects, vertical displacement at and/or near the center of an actuator 20 varies as a function of voltage as well as from actuator to actuator. FIG. 14 illustrates the vertical displacement of various actuators, each similar to the actuator 24 shown in FIG. 5, as a function of voltage. The actuators 24 each have a different piezoelectric film 25 as discussed further below. Axis 170 represents the vertical displacement near the center 98 of each actuator 24 in micrometers, and axis 175 represents the high voltage in volts which is applied to the electrodes included in the actuator, such as, for example, the first electrode 57 as shown in FIG. 5.

The first collection of data points 180 represents the vertical displacement of a first actuator, such as, for example, an actuator similar to the actuator 24 of FIG. 5, having a piezoelectric film 25 of PZN-PT. The first actuator is approximately 450-μm long. The second collection of data points 185 and the third collection of data points 190 represent the vertical displacement of a second actuator and third actuator, respectfully. The second actuator and the third actuator each include a different piezoelectric film 25 of PZN-PT, and are each approximately 450-μm long. The fourth collection of data points 195 represents the vertical displacement of a fourth actuator having a piezoelectric film of lithium niobate approximately 9-μm thick. The high voltage signal applied to each of the actuators varied from approximately 0 V to approximately 200 V.

As shown in FIG. 14, the fourth actuator (i.e., represented by the fourth collection of data points 195) exhibits a weaker response than the first, second, and third actuators. The fourth actuator exhibits little displacement due to the lower piezoelectric coupling of the lithium niobate film 25.

FIG. 14 also shows the vertical displacement for the actuators having PZN-PT films 25 differing primarily by the length and position of the first electrode 57. To some degree, the bending or flexing action of the actuator 24 can also be associated with the actuator 24 exhibiting properties of a unimorph actuator. In some instances, the electrode can act or operate as a passive element and the film 25 can act or operate as an active element.

To test the effectiveness of the vertical field gradient 80 in bowing actuation (e.g., mechanical output), the third actuator is partially coated with an evaporative Cr layer over a large portion or area of the film 25 on the topside 30. The large Cr layer acts as a continuous electrode, such as the continuous electrode 56 illustrated in FIGS. 4 and 5, on the topside 30 of the film 25. Reduced actuation and/or reduced vertical displacement occurs for the third actuator since the electric field distribution is now mostly vertical (e.g., the electric field gradient is reduced). Actuation for the third actuator occurs mainly from the film 25 and the large Cr layer (i.e., a continuous electrode) on the topside 30 operating as a unimorph assembly.

Referring to FIG. 14, the third collection of data points 190 illustrates this reduction in displacement. The third actuator produces an overall flexing of approximately 0.25_{-0.00}^{+0.25}-μm. The third collection of data points 190 indicates that the vertical displacement is reduced and that electric field gradients contribute to the flexing action of the actuators 20.

According to FIG. 14, micron-scale deflections within the actuator 20 occur near and/or above 100 V, which corresponds to an average electric field on the order of approximately 16 kV/cm and higher. The collections of data points 180, 185, 190, and 195 cannot be summarized into a unique functional dependence, because these differences illustrated in FIG. 14 are mostly due to disparities in the electrostatic field and domain distribution. This is a condition affected by the size and position of the first electrode 57 (and/or the continuous electrode 56) as indicated by the first, second, and third collection of data points 180, 185, and 190. In some constructions, the size of the first electrode 57 varies from actuator to actuator by as much as a factor of two.

In some constructions, a uniform vertical electric field gradient present across the thickness 38 of the film 25 produces a displacement y of the actuator 20. The displacement y of the actuator 20 can be expressed as the equation e3

$$y = \frac{{d}_{31} Δ \overline{E} * {L}^{2}}{8 t} \qquad [ e3 ]$$

where d₃₁ is the transverse piezoelectric coefficient, ΔE is the difference in the vertical components of the electric field between the topside 30 and the bottom side 35, L is the length of the film 25 in the absence of an electric field, and t is the thickness of the film 25.

Using the average of the difference in the vertical components (i.e., ΔE) over the length of the film 25, it can be estimated that the transverse piezoelectric coupling coefficient is approximately −1,068 pC/N∓25%. This estimate is based on measured ˜1-μm displacements for 7-μm thick, 0.5-mm long piezoelectric films. The error bars are based on the scatter in the data. In some constructions, the central region 98 under the second electrode 50 is excluded from field averages since it does not contribute to a differential film contraction.

In some constructions and in some aspects, the piezoelectric film 25 of the actuator 20 is constructed from PZN-PT material. In some constructions, an actuator 20 having a PZN-PT film 25 exhibits a small hysteresis loop. The hysteresis loop of a 1-mm long PZN-PT film 25 is illustrated in FIG. 15. Axis 200 represents the vertical deflection of the film 25 in micrometers, and axis 205 represents the excitation voltage in volts. Line 210 represents the deflection of the film 25 as a function of voltage after a first initial excitation, and line 215 represents the deflection of the film 25 as a function of voltage after several excitations. This low hysteresis profile contributes to the reproducibility of the film 25 for use in the actuator 20.

FIG. 16 is another schematic view of an actuator 240, which is similar to the actuator 22 shown in FIG. 3. The actuator 240 includes a piezoelectric film 225 which is similar to the piezoelectric film 25. In the illustrated construction, the piezoelectric film 225 is approximately 5.0-mm long, 1.0-mm wide, and 0.5-mm thick. The piezoelectric film 225 includes a topside 230 and a bottom side 235. A plurality of first electrodes 240 is positioned adjacent to the topside 230 of the film 225. In some constructions, the plurality of first electrodes 240 includes fourteen gold evaporated electrodes approximately 0.7-mm long by 0.3-mm wide. A plurality of second electrodes is also positioned adjacent the bottom side 235 of the film 225. In some constructions, the plurality of second electrodes includes fourteen gold evaporated electrodes approximately 0.7-mm long by 0.3-mm wide. In other constructions, the plurality of first electrodes 240 includes more electrodes than the plurality of second electrodes. In further constructions, the plurality of second electrodes is arranged in different manner on the bottom side 235 of the film 225 than the plurality of first electrodes 240 on the topside 230 of the film 225.

FIGS. 17 and 18 illustrate the vertical bending displacement of the actuator 220 when the plurality of first electrodes 240 and/or the plurality of second electrodes are energized. FIG. 17 illustrates the displacement of the actuator 220 when the plurality of first electrodes 240 is energized. Axis 250 represents the magnitude of the exciting voltage signal in volts, and axis 255 represents the vertical bending displacement of the actuator 220 in microns (micrometers). Line 260 represents the experimental data of the vertical displacement of actuator 220 when excited by various voltage signals. A commercial metrological interferometric microscope, such as the ADE PhaseShift MicroXAM™, performed the measurements. As shown by line 260, the actuator 220 produces a vertical displacement of approximately 2.8-μm when the plurality of first electrodes 240 is energized with a voltage signal of approximately 80 V.

FIG. 18 illustrates the vertical bending displacement of the actuator 220 when the plurality of first electrodes 240 is energized with a first voltage signal and the plurality of second electrodes is energized with a second voltage signal. Axis 270 represents the magnitude of the exciting voltage signal in volts, and axis 275 represents the vertical bending displacement of the actuator 220 in microns (micrometers). Line 280 represents the experimental data of the vertical displacement of actuator 220 when excited by various voltage signals. As shown by lines 260 and 280, the actuator 220 produces larger flexing action when the plurality of first electrodes 240 and the plurality of second electrodes are energized simultaneously (or approximately at the same time). As shown by line 280, the actuator 220 produces a displacement of approximately 4.2-μm when the plurality of first electrodes 240 is energized with a voltage signal of approximately 80 V and the plurality of second electrodes is energized with a voltage signal of approximately −80 V.

In some constructions and in some aspects of the invention, the electric field gradient 80 can be modified by increasing or decreasing the voltage applied to the electrodes 40, 50, 55, 56 and 57. The electric field gradient 80 can also be modified by changing the electrode pattern 45, such as, for example, rearranging the position of one or more first electrodes 40, increasing or decreasing the number of first electrodes 40, etc. Eliminating the second electrode 80 or substituting the second electrode 50 with the plurality of second electrodes 55 or a continuous electrode 56 can also modify the electric field gradient 80. Changes in the electric field gradient 80 will produce changes in the vertical displacement of the actuator 20.

The actuators discussed above have all been fabricated and tested in a similar manner. In some constructions, an actuator, such as, for example, the actuator 20 of FIG. 1, is formed from a bulk crystal plate of piezoelectric material, such as PZN-PT. The bulk material can include, for example, commercially available (001)-oriented bulk crystal plates of 0.955PZN-0.045PT. The thin, single-crystal film 25 is removed from the bulk crystal plate by crystal ion slicing.

In some constructions, the bulk plate is polished prior to crystal ion slicing. For example, a 0.3-μm aluminum-oxide abrasive is used to polish a substantially smooth surface finish on the plate. For crystal ion slicing, ions, such as singly charged 3.8 MeV helium ions, are implanted on a surface of the bulk plate. In other constructions, other implantation energies are used to control the thickness of the film 25 obtained by crystal ion slicing. In one construction, the ions are implanted approximately 5° off normal to the surface of the bulk plate. In some constructions, the ion implant dose is approximately 5×10¹⁶-ions/cm². The bulk plate is mounted to or held by a target holder, such as a 2-in diameter, water-cooled target holder. The target holder also keeps the bulk plate at a relatively constant temperature, such as approximately 58° C. During ion implantation, implantation uniformity can be checked through four Faraday cups positioned outside the target holder.

In some constructions, the bulk plate is treated to post-implantation annealing before the plate undergoes a wet etch that will remove the thin film 25 from the bulk plate. In one construction, the post-implantation anneal is a rapid thermal anneal, such as a 40-s, 550° C. anneal in forming gas of 5% hydrogen and 95% nitrogen. Also in some constructions, the bulk plate is wet etched in commercial 37.5% dilution hydrochloric acid after the post-implantation anneal. A deep undercut typically forms in the bulk plate after approximately an hour. In some constructions, the undercut is centered in the bulk plate at approximately 8-μm below the surface that ions implanted. Typically, etching proceeds at approximately 100-μm/h and yields about a 0.5×1.0-mm² film in roughly a few hours. This film has a thickness of approximately 7-μm.

In one construction, the film, such as the film 25 of FIG. 1, is mounted to a glass slide with the help of a micromanipulator after detachment. The Cr-layer of approximately 50-nm thick is evaporated on one of the topside 30 or the bottom side 35 of the film 25. The film 25 is transferred to an electrode pad with the Cr-layer facing the pad. The electrode pad includes the plurality of first electrodes 40. In some constructions, conductive epoxy clamps are placed on either end of the film 25 so that electrical contact is established between the plurality of first electrodes 40 and the film 25. The center 98 of the film 25 is free to move.

The second electrode 50, a conductive epoxy cover ranging from 50-μm to 100-μm, is deposited on the side 30 or 35 opposite the electrode pad and the first plurality of electrodes 40. The second electrode 50 is positioned substantially near the center 98 of the film 25. Deposition of evaporative metallic films on this side is generally avoided during this procedure to prevent shorting out the two sides 30 and 35 of the film 25.

In some constructions, detection of a vertical displacement of the actuator 20 is performed using the AFM cantilever probe (not shown) and a photodiode sensor (not shown). The AFM probe sensing relies on an optical sectioning mechanism including a spatially limiting detector. In some constructions, the detector is in the form of a pinhole in front of a photodiode (not shown). When the flat surface of the AFM probe lies at the focal point or pinhole, a large signal is detected by the photodiode. If the AFM probe does not lie at the focal point, the measured amplitude as sensed by the photodiode is greatly reduced. A computer-controlled PZT nano-actuator in the sensing head calibrates the displacement data. In some constructions, sinusoidal excitation voltages ranging from approximately 10-Hz to 100-Hz drive the PZN-PT film 25. This AFM-like device is capable of displaying microscopic images of the film 25 to position the probe on a specific location on the film 25. The device can also monitor motion of the film 25 with a resolution of approximately 5-nm.

In most constructions, the AFM probe tip needs to be grounded to avoid spurious electrostatic signals due to charging of the film 25. Thus, an aluminum coating is deposited on the cantilever by thermal evaporation. Displacement tests on the films 25 are also performed by interferometric optical microscopy on a MicroXAM™ non-contact profilometer.

Various features and advantages of the invention are set forth in the following claims.

1. An actuator comprising:
a piezoelectric film having a first side, a second side, and a thickness between the first side and the second side;
a first electrode adjacent the first side of the piezoelectric film;
a second electrode adjacent the second side of the piezoelectric film; and
wherein the first electrode and the second electrode are configured to establish an electric field gradient across the thickness of the film when the first electrode and the second electrode are energized, and wherein the gradient causes deflection of the film, the gradient including a difference between a field component substantially near the first side and a field component substantially near the second side.

2. The actuator as set forth in claim 1, wherein the actuator includes a plurality of first electrodes adjacent the first side.

3. The actuator as set forth in claim 2, wherein the plurality of first electrodes are arranged in a pattern to establish the electric field gradient.

4. The actuator as set forth in claim 2, wherein the plurality of first electrodes are arranged in a pattern to establish substantially stronger first field components near the first side than the second side and stronger second field components near the second side than the first side, the first field components being substantially normal to the second field components.

5. The actuator as set forth in claim 4, wherein the plurality of first electrodes includes electrodes that are substantially parallel and approximately equally spaced.

6. The actuator as set forth in claim 2, wherein the plurality of first electrodes are digitized.

7. The actuator as set forth in claim 2, wherein the plurality of first electrodes includes a first group of first electrodes and a second group of first electrodes, and when the plurality of first electrodes are energized, the first group is energized with a first voltage signal and the second group is energized with a second voltage signal, the first voltage signal being greater than the second voltage signal.

8. The actuator as set forth in claim 1, wherein the second electrode includes a second plurality of electrodes.

9. The actuator as set forth in claim 1, wherein the actuator includes a plurality of first electrodes and a plurality of second electrodes, the plurality of first electrodes is arranged in a first pattern and the plurality of second electrodes is arranged in a second pattern, and when the plurality of first electrodes and the plurality of second electrodes are energized, the first pattern and second pattern contribute to the electric field gradient.

10. The actuator as set forth in claim 1, wherein the piezoelectric film is of a material selected from the group consisting of (1-x)Pb(Zn_{1/3}Nb_{2/3})O₃-xPbTiO₃, (1-x)Pb(Mg_{1/3}Nb_{2/3})O₃-xPbTiO₃, Pb(ZrTi)O₃, and LiNbO₃.

11. The actuator as set forth in claim 1, wherein the field component substantially near the first side of the film is substantially greater than the field component substantially near the second side of the film.

12. The actuator as set forth in claim 1, wherein the difference between the field component substantially near the first side and the field component substantially near the second side includes a difference between an average field component substantially near the first side and an average field component substantially near the second side.

13. The actuator as set forth in claim 12, wherein the average field component substantially near the first side of the film has a first direction and the average field component substantially near the second side of the film has a second direction; and
wherein the difference between the average field component substantially near the first side and the average field component substantially near the second side is a difference between the first direction and the second direction.

14. The actuator as set forth in claim 12, wherein the average field component substantially near the first side of the film has a first magnitude and the average field component substantially near the second side of the film has a second magnitude; and
wherein the difference between the average field component substantially near the first side and the average field component substantially near the second side is a difference between the first magnitude and the second magnitude.

15. The actuator as set forth in claim 1, wherein the field component substantially near the first side of the film has a first direction and the field component substantially near the second side of the film has a second direction; and
wherein the difference between the field component substantially near the first side and the field component substantially near the second side is a difference between the first direction and the second direction.

16. The actuator as set forth in claim 1, wherein the field component substantially near the first side of the film has a first magnitude and the field component substantially near the second side of the film has a second magnitude; and
wherein the difference between the field component substantially near the first side and the field component substantially near the second side is a difference between the first magnitude and the second magnitude.

17. The actuator as set forth in claim 2, wherein the plurality of electrodes are digitized and the second electrode is grounded.

18. The actuator as set forth in claim 1, wherein the deflection of the film is induced by the electric field gradient such that one of the first side and the second side contracts more than the other of the first side and the second side.

19. The actuator as set forth in claim 1, wherein the deflection of the film results from a differential contraction between the first side of the film and the second side of the film.

20. The actuator as set forth in claim 1, wherein the first electrode is energized with a first voltage signal and the second electrode is energized with a second voltage signal.

21. The actuator as set forth in claim 20, wherein the first voltage signal has a first magnitude and the second voltage signal has a second magnitude, the first magnitude differing from the second magnitude.

22. The actuator as set forth in claim 20, wherein the first voltage signal has a first phase and the second voltage signal has a second phase, the first phase differing from the second phase.

23. The actuator as set forth in claim 1, wherein the piezoelectric film is poled, and wherein the first electrode and second electrode serve as pole pieces during a poling process of the piezoelectric film.

24. An actuator comprising:
a piezoelectric film having a first side, a second side, and a thickness between the first side and second side; and
a plurality of electrodes positioned adjacent to the piezoelectric film and establishing an electric field gradient across the thickness of the film when the plurality of electrodes are energized, the gradient deflecting the film.

25. The actuator as set forth in claim 24, wherein the plurality of electrodes include a plurality of first electrodes adjacent the first side and a second electrode adjacent the second side.

26. The actuator as set forth in claim 25, wherein the plurality of first electrodes are arranged in a pattern to establish the electric field gradient when the plurality of first electrodes is energized.

27. The actuator as set forth in claim 26, wherein the plurality of first electrodes includes electrodes that are substantially parallel and approximately equally spaced.

28. The actuator as set forth in claim 25, wherein the plurality of first electrodes are digitized.

29. The actuator as set forth in claim 25, wherein the plurality of first electrodes includes a first group of first electrodes and a second group of first electrodes, and when the plurality of first electrodes are energized, the first group is energized with a first voltage signal and the second group is energized with a second voltage signal, the first voltage signal approximately greater than the second voltage signal.

30. The actuator as set forth in claim 24, wherein the plurality of electrodes includes a plurality of first electrodes and a plurality of second electrodes, the plurality of first electrodes is arranged in a first pattern and the plurality of second electrodes is arranged in a second pattern, and when the plurality of first electrodes and the plurality of second electrodes are energized, the first pattern and second pattern contribute to the electric field gradient.

31. The actuator as set forth in claim 24, wherein the piezoelectric film is of a material selected from the group consisting of (1-x)Pb(Zn_{1/3}Nb_{2/3})O₃-xPbTiO₃, (1-x)Pb(Mg_{1/3}Nb_{2/3})O₃-xPbTiO₃, Pb(ZrTi)O₃, and LiNbO₃.

32. The actuator as set forth in claim 24, wherein the gradient includes a difference between a field component substantially near the first side of the film and a field component substantially near the second side of the film.

33. The actuator as set forth in claim 32, wherein the field component substantially near the first side of the film is substantially greater than the field component substantially near the second side of the film.

34. The actuator as set forth in claim 32, wherein the difference between the field component substantially near the first side and the field component substantially near the second side includes a difference between an average field component substantially near the first side and an average field component substantially near the second side.

35. The actuator as set forth in claim 34, wherein the average field component substantially near the first side has a first direction and the average field component substantially near the second side has a second direction; and
wherein the difference between the average field component substantially near the first side and the average field component substantially near the second side is a difference between the first direction and the second direction.

36. The actuator as set forth in claim 35, wherein the first direction is substantially vertical with respect to the thickness of the film and the second direction is substantially horizontal with respect to the thickness of the film.

37. The actuator as set forth in claim 34, wherein the average field component substantially near the first side has a first magnitude and the average field component substantially near the second side has a second magnitude; and
wherein the difference between the average field component substantially near the first side and the average field component substantially near the second side is a difference between the first magnitude and the second magnitude.

38. The actuator as set forth in claim 32, wherein the field component substantially near the first side has a first direction and the field component substantially near the second side has a second direction; and
wherein the difference between the/field component substantially near the first side and the field component substantially near the second side is a difference between the first direction and the second direction.

39. The actuator as set forth in claim 38, wherein the first direction is substantially vertical with respect to the thickness of the film and the second direction is substantially horizontal with respect to the thickness of the film.

40. The actuator as set forth in claim 32, wherein the field component substantially near the first side has a first magnitude and the field component substantially near the second side has a second magnitude; and
wherein the difference between the field component substantially near the first side and the field component substantially near the second side is a difference between the first magnitude and the second magnitude.

41. The actuator as set forth in claim 24, wherein the gradient causes one of the first side and the second side to contract more than the other of the first side and the second side.

42. The actuator as set forth in claim 24, wherein the gradient causes a differential contraction between the first side of the film and the second side of the film.

43. The actuator as set forth in claim 24, wherein the plurality of electrodes are digitized.

44. The actuator as set forth in claim 24, wherein the plurality of electrodes is adjacent one of the first side of the piezoelectric film and the second side of the piezoelectric film.

45. The actuator as set forth in claim 24, wherein piezoelectric film is poled, and wherein the plurality of electrodes serve as pole pieces during a poling process of the piezoelectric film.

46. A method of converting an electrical input to a mechanical output by way of a single piezoelectric film, the film having a first side, a second side and a thickness, the method comprising:
positioning a first electrode adjacent one of the first side and the second side of the piezoelectric film;
positioning a second electrode adjacent one of the first side and the second side of the piezoelectric film;
energizing the first electrode and the second electrode to produce an electric field gradient across the thickness of the piezoelectric film; and
deflecting the film in response to the presence of the electric field gradient.

47. The method as set forth in claim 46, wherein deflecting the film in response to the presence of the electric field gradient includes causing differential contraction of one of the first side and the second side of the piezoelectric film relative to the other one of the first side and second side.

48. The method as set forth in claim 46, wherein energizing the first electrode and the second electrode to produce an electric field gradient across the thickness of the piezoelectric film includes energizing the first electrode with a high voltage signal and energizing the second electrode with a low voltage signal, energizing the first electrode and second electrode producing the electric field gradient across the thickness of the piezoelectric film.

49. The method as set forth in claim 46, wherein positioning a first electrode adjacent one of the first side and the second side of the piezoelectric film includes positioning a plurality of first electrodes adjacent the first side the piezoelectric film; and
wherein energizing the first electrode and the second electrode to produce an electric field gradient across the thickness of the piezoelectric film includes energizing the plurality of first electrodes and the second electrode to produce the electric field gradient across the thickness of the piezoelectric film.

50. The method as set forth in claim 49, wherein positioning a plurality of first electrodes adjacent the first side of the piezoelectric film includes arranging the plurality of electrodes into a pattern to contribute to the electric field gradient.

51. The method as set forth in claim 46, wherein energizing the first electrode and the second electrode to produce an electric field gradient across the thickness of the piezoelectric film includes energizing the first electrode and the second electrode to produce an electric field gradient having a difference between an average field component substantially near the first side of the film and an average field component substantially near the second side of the film.

52. The method as set forth in claim 46, wherein positioning the first electrode adjacent one of the first side and the second side of the piezoelectric film and positioning the second electrode adjacent one of the first side and the second side of the piezoelectric film includes positioning the first electrode and the second electrode adjacent the first side of the piezoelectric film.

53. The method as set forth in claim 46, wherein positioning the first electrode adjacent one of the first side and the second side of the piezoelectric film and positioning the second electrode adjacent one of the first side and the second side of the piezoelectric film includes positioning the first electrode adjacent the first side and positioning the second electrode adjacent the second side.
